(19) United States
(12) Patent Application Publication
(10) Pub. No.: US 2006/0037538 A1
(43) Pub. Date: Feb. 23, 2006

(54) Holding device for a screen

(76) Inventors: Andreas Sauer, Grossostheim (DE); Harald Wurster, Mombris (DE); Gerhard Joos, Obernburg (DE); Guido Hattendorf, Brachttal (DE)

Correspondence Address: VAN DYKE, GARDNER, LINN AND BURKHART, LLP, 2851 CHARLEVOIX DRIVE, S.E., P.O. BOX 888695, GRAND RAPIDS, MI, 49588-8695, US

(21) Appl. No.: 11/171,996

(22) Filed: Jun. 30, 2005

(30) Foreign Application Priority Data
Aug. 17, 2004 (EP) 04 019 521.6

(51) Int. Cl. C23C 16/00

(52) U.S. Cl. 118/720

(57) ABSTRACT

A holding device 12 for mounting at least one screen 9 in a coating chamber 2 of an installation for coating a substrate, especially a glass substrate, is configured such that a screen 9 held by the holding device 12 can be moved at least from a first position within the coating chamber 2 to a second position by movement of the holding device 12. The holding device 12 has means 13 of such kind as to enable the screen 9 to avoid obstructions on the way from the first position to the second position. In particular, during its movement from the first to the second position, the screen 9 is mounted slewably on the holding device 12.

The invention relates to a holding device for mounting at least one screen in a coating chamber of an installation for coating a substrate, especially a glass substrate, said holding means being configured such that a screen held by the holding means can be moved at least from a first position within the coating chamber to a second position by movement of the holding device.

It is known practice to mount screens inside the coating chamber of coating lines, for example glass-coating lines; the screens effect the necessary shielding of certain areas of the chamber and make for selective and uniform coating of the glass substrate. Screens are used especially in the cathode zone of glass-coating lines. This applies both to coating lines with planar cathode bodies and to lines with rotating cathode bodies.

To permit removal of the screens from the coating chamber for purposes of maintenance or cleaning, an access aperture is provided in the coating chamber, usually in the area above the cathodes. The cathodes can be exchanged through this access aperture. The aperture additionally provides access, when necessary, to the other components of the coating line, especially the screens.

However, as seen from the access aperture, at least one section of the screens is usually located underneath the cathode, that is, in the space between the cathodes and the substrate. This section can form an interference edge with the cathode mounted above it. Screens that are permanently installed or attached to a frame therefore have the disadvantage that they can only be removed after the cathode bodies have been removed. In other words, access to screens that partially surround the cathodes is only possible at the time of or after removal of the cathodes from the coating chamber. This reduces the efficiency of the coating line, as additional assembly steps are needed and time is lost.

The use of so-called cantilevered cathodes is especially problematic because these cathodes are mounted laterally through the recipient wall, in which they remain after the coating chamber is opened. The necessity of removing a target or cathode prior to a screen change is especially time-consuming in this case.

Against this background, the object of the present invention is to facilitate removal of the screens from a coating line. This applies particularly to the removal of screens that at least partially encompass the cathodes.

This object is established by provision of a screen-holding device with the features of claim 1.

The invention relates to a holding device for mounting at least one screen in a coating chamber of an installation for coating a substrate, especially a glass substrate, said holding means being configured such that a screen held by the holding means can be removed at least from an operative position (first position) within the coating chamber by movement of the holding device. The screen is removed from the coating chamber to a second position outside the coating chamber. The holding device has means of such kinds as to enable the screen to avoid obstruction while the screen is removed from said operative position within the coating chamber.

The movable holding device permits the screen connected to it to be removed from the coating chamber. The holding device is typically configured such that one section extends into the area of the access aperture and may or may not be connected with the cover flange for closing the access aperture. In the latter case, the screens are moved away from their operative position when the flange is lifted off the opening.

Since the screens are usually required to provide partial shielding also on the substrate side, that is, on the side facing away from the access aperture, one section of the screens, as seen from the access aperture, is located underneath a cathode. When the screens are in the operative position, this portion of the screen would be obstructed by, that is, would collide with, the cathode mounted above it if a conventional holding device were pulled linearly out of the chamber.

Use of the holding device according to the invention prevents any contact between the screens and the cathodes, the chamber walls and possibly other coating-line components mounted in the chamber when the screens are removed from the chamber. It can thus be ensured that, without removing the cathodes from the coating chamber, neither the screens nor the cathodes will be damaged on withdrawing the screens. Despite the cathode being partially encompassed by the screens, damage to or jamming of the screens is ruled out because the holding device prevents the screen from touching obstructions located in its path.

Once they have been removed from the coating chamber, the screens can easily be detached from the corresponding supports prior to servicing and cleaning. Time-consuming removal of the cathodes prior to withdrawing the screens is unnecessary. The saving in assembly work and time makes for more efficient use of the coating line.

The means are preferably configured such that when the screen moves from the first position to the second position, it can perform at least one additional movement relative to the holding device.

The additional movement superposed on the movement of the screen as it is withdrawn from the coating chamber can be a rotational or a translational movement. This additional movement enables the screen, while on its way from the operative position to the aperture, to avoid possible obstructions, such as a cathode, with which it forms an interference edge when in the operative position.

In particular, the means are configured such that on its way from the first position to the second position, the screen can change its orientation in the coating chamber. This means the screen can be tilted relative to its original operative position. Thus, while the screen is passing an obstruction, contact therewith can be avoided by means of a controlled and selective change in the screen's orientation.

The means are configured particularly to allow swivelling of the screen relative to the holding device. This measure makes it possible, for example when the screen is passing the cathode during withdrawal of the holding device from the coating chamber, to tilt the screen and thus to guide a projection that is located behind the cathode when the screen is in the operative position past the cathode without touching it.

The means can include, for example, a hinged joint for swivelling the screen.

The screen can be attached, in particular, to a slewable portion of the holding device. This means that the holding device consists of two pivoted parts. One part can be connected with the cover flange for closing the aperture, while the other part has the screen attached thereto.

Alternatively, the means can be configured such that the screen, while on the way from the first position to the second position, can perform a lateral displacement relative to the holding device. This means that the screen can avoid an obstruction by moving sideways on the holding device, generally at right angles to the direction of the movement from the first to the second position, away from the obstruction. Which configuration is chosen depends, among other things, on the arrangement of the components in the chamber.

The means are preferably configured such that the orientation and/or the lateral displacement of the screen depends on the position of the screen on the way from the first position to the second position. By means of the relation between the position of the screen, especially the distance between it and the access aperture (in other words, how high up the screeen is), and the degree to which it is slewed or displaced, a collision with an obstruction is prevented during every phase of the movement to the second position. The location of the screen can be determined in various ways and the evasion means adjusted appropriately.

Changing the screen's orientation and/or displacing it laterally can be effected mechanically, for instance, especially by the action of gravity or of a spring force. For example, simply lifting the screen off a supporting surface, such as the surface of a cooling unit, can cause the screen to swivel away from the cathode. To this end, all that is necessary is to select the screen's centre of gravity such that when the holding device is raised, a suitable torque acts on the screen and causes it to swivel by a desired angle about the pivot. This arrangement is particularly uncomplicated and economical in production and operation. No external energy is required, and no external control.

Another option for changing the orientation and/or for displacing the screen laterally is to effect this electronically.

It is preferable for the change in orientation and/or for the lateral displacement of the screen during its movement from the first position to the second position to be effected in sel-facting manner. This can be realised, for example, by raising the screen from a supporting surface and exposing it to the action of gravity, by automatic acitvation of a spring at a certain point on the way, by providing a guide means for the screen, by automatic activation of a switch when the screen passes through a specified zone, or by any other methods familiar to a person versed in the art.

The change in orientation and/or the lateral displacement of the screen is brought about particularly by the movement of the screen from the first position to the second position. The screen is limited in its freedom of movement when passing an obstruction.

It is preferable for the change in orientation and/or for the lateral displacement of the screen during its movement from the first position to the second position to be effected automatically. In this connection, the term “automatically” refers to any change that takes place without intervention on the part of the user. Any failure of the system due to human error or carelessness is thus ruled out.

The first position is typically an operative position within the coating chamber, and is the intended position for the screen during coating operations.

The second position is typically a maintenance position offering essentially free access to the screen. It can be located inside or outside the coating chamber. The second position can be a position near the coating chamber's access aperture or a position outside the coating chamber.

Particularly during movement of the screen from the first to the second position, the holding device performs an essentially linear movement. If the holding device is attached, for example, to the flange for closing the aperture, vertical lifting of the flange to open the aperture will result in an essentially linear movement of the support. The interference edges are thus clearly defined, and the screen can automatically perform the correct movements relative to the holding device in order to prevent collisons.

When located in the first position, the screen can at least partially encompass a cathode mounted inside the coating chamber. In particular, the screen projects behind the cathode and thus produces interfering edges; however, thanks to the additional movement of the screen relative to the holding device, as provided for in the device of the invention, the interfering edges are eliminated when the screen is removed.

When mounted in the first position, the screen is preferably in contact with a cooling unit. The heat generated during the coating process can be dissipated by an appropriate cooling unit. The cooling unit will typically be a water-based cooling unit. A portion of the screen can be supported on a cooling surface so as to produce the best possible thermal contact. This contact can be achieved, for instance, by way of the lid weight or, if the coating line is evacuated, by the differential pressure. An adequate downforce is thus provided. To obtain a relatively uniform contact pressure that can also be regulated, additional use can be made of springs.

When it moves from the first position to the second position, the screen preferably detaches from the cooling unit. Theoretically, the water-based cooling unit can be permanently connected with the screens, in which case it must be removed from the coating chamber together with the screens. However, provided it is only in contact with the screens, the cooling unit can also be left in the coating chamber. With this embodiment, the screens can be changed very quickly for cleaning purposes as they need only be anchored with simple hinge pins, and need not be connected to the cooling unit with a large number of bolts as in conventional equipment.

Additional features and advantages of the invention become apparent from the following description of a specific embodiment.

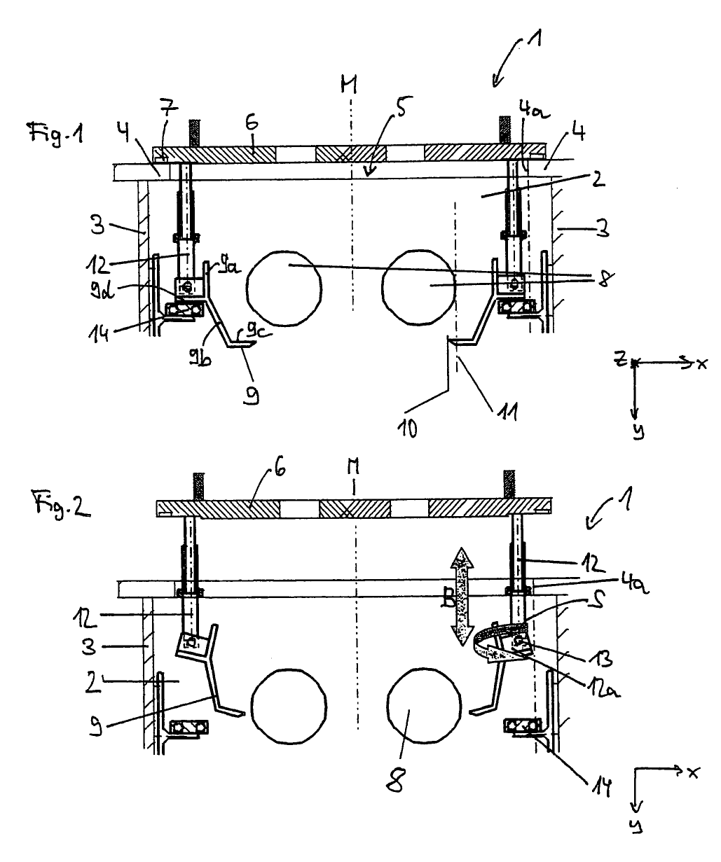

FIG. 1 shows a vertical section through part of a coating line with various components in the operative position;

FIG. 2 shows the coating line as the coating chamber is opened.

FIG. 1 shows part of a coating line 1. It has a coating chamber 2 with side walls 3 and a top wall area 4. The top wall area is perforated by an access aperture 5 that allows access to the coating chamber 2. In particular, the access aperture 5 provides access for the purpose of exchanging the cathode bodies 8 and for maintenance work on the other components of the coating line 1, especially the screens 9.

As shown in FIG. 1, the access aperture 5 is closed with a cover flange 6 while the coating line 1 is in operation. Vacuum-tight closure of the coating line 2 is ensured by seals 7, for example sealing rings, which are accommodated in grooves.

In the embodiment, two cathode bodies 8 that are engineered as rotating cathodes are provided in the coating chamber 2. The cathode bodies 8 are essentially cylindrical in shape. Obviously, however, it is also possible to use planar instead of rotating cathodes in the coating chamber 2.

In the sectional view illustrated, the screen 9 is angled in the vertical x-y plane. One section 9a of the screen runs parallel to the y-axis, an adjacent section 9b slopes towards the target 8, and one section 9c runs parallel to the x-axis towards the center line M. This arrangement means that the target 8 is partially encompassed by the relevant screen 9.

Each of the cathode bodies 8 is shielded laterally in the direction parallel to the x-axis by sections 9a and 9b of the screen 9. In addition, the cathode 8 is shielded to a small extent in the downward direction towards the substrate (i.e. in the y-direction) by section 9c of the screen 9. From above, that is, as seen from the access aperture 5, the distal section 9c of the screen 9 is located behind a cathode body 8 when in the operative state, as a result of which a projecting end 10 is formed that extends beyond an interference edge 11—that runs parallel to the y-axis—of the cathode 8.

When in the operative position, the screen 9 makes contact with a water-based cooling unit 14 via a flange 9d. The heat generated during the coating process can be dissipated by the cooling unit 14. By way of firm downward pressure, good thermal contact is established between the screen 9 and the cooling unit 14. This contact can be achieved, for instance, by means of the weight of the flange 6 or, if the coating chamber 2 is evacuated, by the differential pressure.

FIG. 2 illustrates the coating line 1 during opening of the coating chamber 2 by removal of the cover flange 6. The cover flange 6 can be raised and lowered in the directions indicated by the arrow B.

The supports 12 are connected with the cover flange 6. Accordingly, when the cover flange 6 is lifted vertically, the supports 12 move vertically upwards with it.

As the cover flange 6 and the support 12 move upwards, the screen 9, which, in its operative position, rests on the contact surface of the cooling unit 14, is lifted off the contact surface and up towards the aperture 5.

The projecting end 10, shown in FIG. 1, of the screen section 9c extends beyond the interference edge 11 of the cathode 8 towards the centre line M and would collide with the cathode body 8 during upward movement if the connection between the cover flange 6 and the screen 9 were completely rigid. A collision with or even just contact with the cathode body 8 could prevent removal of the screen 9 from the coating chamber 2 and could also result in damage.

For this reason, the holding devices 12 are provided with a joint, for example a pivot 13. One part of the support 12 is connected at its upper end with the flange 6, while the other part 12a of the support 12 is rigidly connected with the screen 9. The part 12a is disposed in an angle formed by the sections 9a and 9d of the screen 9.

The two parts of the holding device 12 are connected together by a hinged joint, and are therefore slewable relative to one another. To this end, a pivot 13 can be provided at the lower end of the support 12, which pivot interacts with a corresponding bearing bush (not illustrated) in the other part 12a of the support 12. In the drawing, the pivot runs perpendicular to the x-y plane.

When the cover flange 6 is lifted, as already described, the screen 9 is lifted off the contact surface of the cooling unit 14. The assembly was engineered such that the centre of gravity of the combination comprising the screen 9 and the part 12a of the support 12 is displaced—in relation to the pivot 13—towards the centre line M. When the screen is raised, therefore, the gravitational force acting on the assembly 9, 12a is displaced laterally with respect to the pivot and exerts a torque on the assembly. As a result, the assembly 9, 12a is swung downwards. In FIG. 2, the slewing direction is indicated by the arrow S. The screen 9 is thus swung sufficiently far outwards and away from the centre line M and the cathode 8 in the x-y plane for the overlap 10 with the cathode to be eliminated. As a result, the screen 9 can pass the cathode 8 without touching it. The amount of slew is furthermore calculated such that the assembly comprising the screen 9 and the part 12a can be guided through the aperture 5 without touching the edge 4a of the top wall 4. These measures permit safe removal of the screens 9 from the coating chamber 2, without first having to remove the cathode bodies 8.

In the example described, the part 12a is caused to rotate by gravity. Alternatively, however, spring forces or other mechanical or electronic means can be used to effect a forced, automatic or at least self-acting movement of the screen 9 relative to the upper part of the support 12 in order to prevent a collision with the cathode 8. For example, a control system could be incorporated that coordinates the slewing movement S as a function of the translational movement B in such manner that the screen 9 can be guided to the access aperture 5 without colliding with the cathode body 8 or a component of the coating line 1. The mechanism by which the slewing movement S is coordinated as a function of the translational movement B could, for example, consist in controlling S as a function of the y-coordinate of the pivot 13, it being preferable to allocate specified slewing angles to specified y-coordinates. A movement B of the supports 12 forces the screen 9 to rotate about the pivot 13. In other words, the slewing movement S is effected automatically by the movement B. This means that during removal of the screens 9 from the coating chamber 2, human error and damage to components of the coating line 1 are largely ruled out. Both the control system and the slewing movement itself can be realised both mechanically and electronically.

The heat generated at the screen 9 during the coating process can be dissipated by the cooling element 14. As shown in FIG. 2, the water-based cooling unit 14 can remain in the coating chamber when the screens 9 are removed. In the embodiment, the screen 9 detaches from the cooling element on being lifted off the contact surface of the cooling unit 14. Good thermal contact between the cooling unit 14 and the screen 9, especially between the cooling unit 14 and section 9d of the screen 9, is guaranteed by a high and balanced downward force. The length of the support 12 is preferably adjustable. To regulate the downward force, the support 12 can additionally be provided with springs that generate a uniform pressure on the screen section 9d.

In theory, however, it is also possible for the water-based cooling unit 14 to be firmly connected with the screens 9, in which case it is removed from the coating chamber 2 together with the screens.

The coating line illustrated offers the possibility of a quick change of screens 9 for cleaning or maintenance purposes, in particular without the need to remove the cathode bodies 8.

### LIST OF REFERENCE NUMERALS (WURDE NICH AN AVS ÜBERSANDT!!)

1 Coating line
2 Coating chamber
3 Side walls
4 Top wall area
4a Edge of wall area
5 Access aperture
6 Cover flange
7 Seal
8 Cathode body
9 Screen
9a-9d Screen sections
10 Projecting end
11 Cathode interference edge
12 Support
12a a Lower part of support
13 Pivot
14 Water-based cooling unit
M Centre line
B Direction of movement
S Slewing movement

1-20. (canceled)

21. A coating installation for coating a substrate, said installation comprising:
a coating chamber;
a holding device; and
a screen held by said holding device, said holding device being configured such that said screen held by said holding device can be removed from said coating chamber at least from an operative position within said coating chamber by movement of the holding device to a position outside said coating chamber, and said screen being configured with said holding device to enable said screen to avoid obstructions while being removed from said coating chamber.

22. The coating installation according to claim 21, wherein said screen is configured with said holding device such that while said screen is moved from said operative position within said coating chamber to the position outside said coating chamber, said screen can perform at least one additional movement relative to said holding device.

23. The coating installation according to claim 21, wherein said screen is configured with said holding device such that while said screen is removed from said operative position within said coating chamber to the position outside said coating chamber, said screen can change its orientation while in said coating chamber.

24. The coating installation according to claim 21, wherein said screen is configured with said holding device to allow pivoting of said screen relative to said holding device to thereby enable said screen to avoid obstructions while being removed from said coating chamber.

25. The coating installation according to claim 24, wherein said means comprises a hinged joint, said hinged joint allowing pivoting of said screen.

26. The coating installation according to claim 25, wherein said holding device has a pivoting portion, said screen being attached to said pivoting portion.

27. The coating installation according to claim 21, wherein said screen is configured with said holding device such that said screen while being removed from said operative position within said coating chamber to the position outside said coating chamber can perform a lateral displacement relative to said holding device.

28. The coating installation according to claim 21, wherein said screen is configured with said holding device such that an orientation and/or a lateral displacement of said screen depends on the position of said screen in said coating chamber when said screen is removed from said operative position within said coating chamber to the position outside said coating chamber.

29. The coating installation according to claim 28, wherein said change in orientation and/or lateral displacement of said screen is effected mechanically or electronically.

30. The coating installation according to claim 29, wherein said change in orientation and/or lateral displacement of said screen is effected by the action of gravity or of a spring force.

31. The coating installation according to claim 28, wherein said change in orientation and/or lateral displacement of said screen is effected in a self-acting manner while said screen is removed from said operative position in said coating chamber to said position outside said coating chamber.

32. The coating installation according to claim 28, wherein said change in orientation and/or lateral displacement of the said screen is forced while said screen is being removed from said operative position in said coating chamber to said position outside said coating chamber.

33. The coating installation according to claim 28, wherein said change in orientation and/or lateral displacement of said screen is effected automatically while said screen is removed from said operative position in said coating chamber to said position outside said coating chamber.

34. The coating installation according to claim 21, wherein said operative position is in the intended position for said screen during a coating operation within said coating chamber.

35. The coating installation according to claim 21, wherein said position outside the coating chamber is a maintenance position offering essentially free access to said screen.

36. The coating installation according to claim 35, wherein said maintenance position is a position near an access aperture of said coating chamber and/or a position outside the coating chamber.

37. The coating installation according to claim 21, wherein said holding device forms an essentially linear movement while said screen is removed from said operative position within said coating chamber to said position outside said coating chamber.

38. The coating installation according to claim 21, wherein said screen at least partially encompasses a cathode mounted inside said coating chamber when said screen is located in said operative position in said coating chamber.

39. The coating installation according to claim 21, wherein said screen is in contact with a cooling unit when mounted in said operative position in said coating chamber.

40. The coating installation according to claim 39, wherein said screen detaches from said cooling unit when said screen is removed from said operative position within said coating chamber to said maintenance position.
